(19) United States
(12) Patent Application Publication
(10) Pub. No.: US 2026/0352183 A1
(43) Pub. Date: Nov. 5, 2026

(54) Vibrator Device

(71) Applicant: SEIKO EPSON CORPORATION, Tokyo (JP)

(72) Inventor: Yusuke MATSUZAWA, Chino (JP)

(21) Appl. No.: 19/662,346

(22) Filed: Apr. 29, 2026

(30) Foreign Application Priority Data
Apr. 30, 2025 (JP) 2025-075234

(51) Int. Cl. H03H 9/17; H03H 9/13

(52) U.S. Cl. CPC H03H 9/17; H03H 9/13

(57) ABSTRACT

A vibrator device 1 includes: a semiconductor substrate 5 including through electrodes 51, 52, 53, and 54; a wiring layer 7 provided on an upper surface 5a of the semiconductor substrate 5 and including four conductive layers 7a, 7b, 7c, and 7d, the conductive layers 7a, 7b, 7c, and 7d including conductive sections 71 and 72 and conductive sections 73, 74, 75, and 76 that are electrically connected to the through electrodes 51, 52, 53, and 54, respectively; a group of terminals 500 provided on a lower surface 5b of the semiconductor substrate 5, the group of terminals 500 including a terminal 510 to which a VDD is supplied and that is electrically connected to the through electrode 51, a terminal 520 to which a VSS is supplied and that is electrically connected to the through electrode 52, a terminal 530 to which a control signal is input and that is electrically connected to the through electrode 53, and a terminal 540 from which a clock signal as an output signal is output and that is electrically connected to the through electrode 54; and a vibrator element 3 provided on the upper surface 5a side of the semiconductor substrate 5 and connected to the conductive sections 71 and 72 via bonding members B1 and B2.

The present application is based on, and claims priority from JP Application Serial Number 2025-075234, filed Apr. 30, 2025, the disclosure of which is hereby incorporated by reference herein in its entirety.

### BACKGROUND

### 1. Technical Field

The present disclosure relates to a vibrator device.

### 2. Related Art

JP-A-2004-128591 describes a piezoelectric oscillator including a piezoelectric vibrator in which an excitation electrode is formed on a piezoelectric element plate and a semiconductor integrated component in which an oscillation circuit is formed, in which the piezoelectric vibrator is directly mounted on and connected to the semiconductor integrated component, a lid is disposed on the semiconductor integrated component to cover the piezoelectric vibrator, and the piezoelectric oscillator is mounted on a user's mounting substrate using a connection electrode disposed on a surface of the semiconductor integrated component opposite to a surface on which the piezoelectric vibrator is mounted.

In such an oscillator, further deepening of the technology for realizing miniaturization is required.

### SUMMARY

A vibrator device according to an aspect of the present disclosure includes: a semiconductor substrate having a first surface and a second surface that are opposite each other, and including a first through electrode, a second through electrode, a third through electrode, and a fourth through electrode that extend through the first surface and the second surface; a wiring layer provided on the first surface of the semiconductor substrate and including at least four conductive layers stacked via insulating films, the at least four conductive layers including a first conductive section, a second conductive section, a third conductive section electrically connected to the first through electrode, a fourth conductive section electrically connected to the second through electrode, a fifth conductive section electrically connected to the third through electrode, and a sixth conductive section electrically connected to the fourth through electrode; a group of terminals provided on the second surface of the semiconductor substrate, the group of terminals including a first terminal to which a first potential is supplied and that is electrically connected to the first through electrode, a second terminal to which a second potential different from the first potential is supplied and that is electrically connected to the second through electrode, a third terminal to which a control signal is input and that is electrically connected to the third through electrode, and a fourth terminal from which an output signal is output and that is electrically connected to the fourth through electrode; and a vibrator element provided on the first surface side of the semiconductor substrate and electrically connected to the first conductive section and the second conductive section via bonding members.

### BRIEF DESCRIPTION OF THE DRAWINGS

FIG. 1 is a top perspective view of a vibrator device of the present embodiment.

FIG. 2 is a bottom perspective view of the vibrator device.

FIG. 3 is a sectional view of the vibrator device taken along line A-A in FIG. 1.

FIG. 4 is a sectional view of the vibrator device taken along line B-B in FIG. 1.

FIG. 5 is a plan view illustrating wiring and a wiring layer of a base substrate of the vibrator device.

FIG. 6 is a block diagram illustrating a circuit configuration of the vibrator device.

FIG. 7 is a flowchart illustrating a process for manufacturing the vibrator device.

FIG. 8 is a sectional view illustrating an aspect of the process for manufacturing the vibrator device.

FIG. 9 is a sectional view illustrating an aspect of the process for manufacturing the vibrator device.

FIG. 10 is a sectional view illustrating an aspect of the process for manufacturing the vibrator device.

### DESCRIPTION OF EMBODIMENTS

Hereinafter, an embodiment of the present disclosure will be described with reference to the drawings.

In each of the following drawings, in order to make each of the components easier to see, the dimensions of the components may be illustrated on different scales.

In addition, hereinafter, for convenience of description, three axes orthogonal to each other are set as an X-axis, a Y-axis, and a Z-axis, and a direction parallel to the X-axis is referred to as an “X-axis direction”, a direction parallel to the Y-axis is referred to as a “Y-axis direction”, and a direction parallel to the Z-axis is referred to as a “Z-axis direction”.

Further, a tip side of each axis in an arrow direction is referred to as a “plus side”, and the opposite side is referred to as a “minus side”.

A view from a plus side in the Z-axis direction toward a minus side in the Z-axis direction is referred to as a “plan view”.

A surface on the plus side in the Z-axis direction is referred to as an “upper surface”, and a surface on the minus side in the Z-axis direction is referred to as a “lower surface”.

### 1. Embodiment 1

### 1.1. Schematic Configuration of Vibrator Device

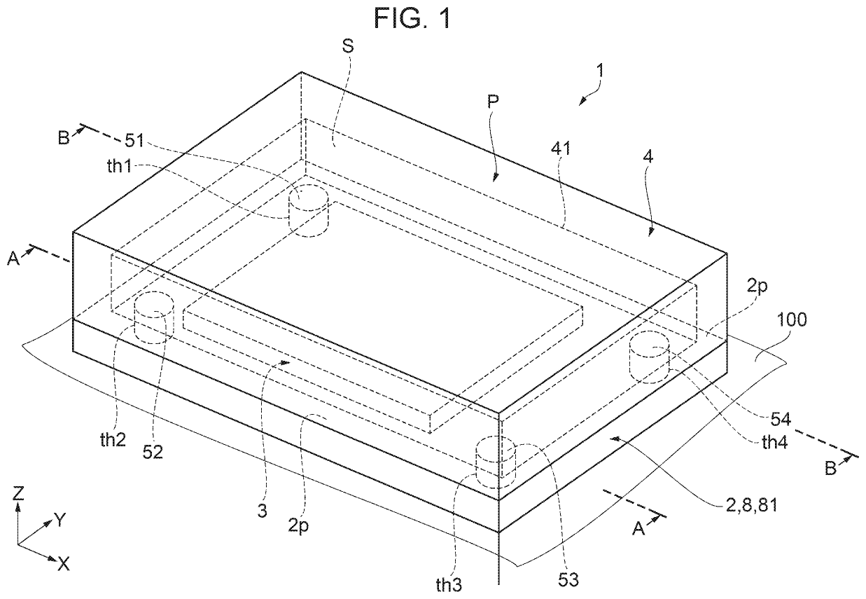

FIGS. 1 to 6 illustrate a configuration of a vibrator device 1 according to the present embodiment.

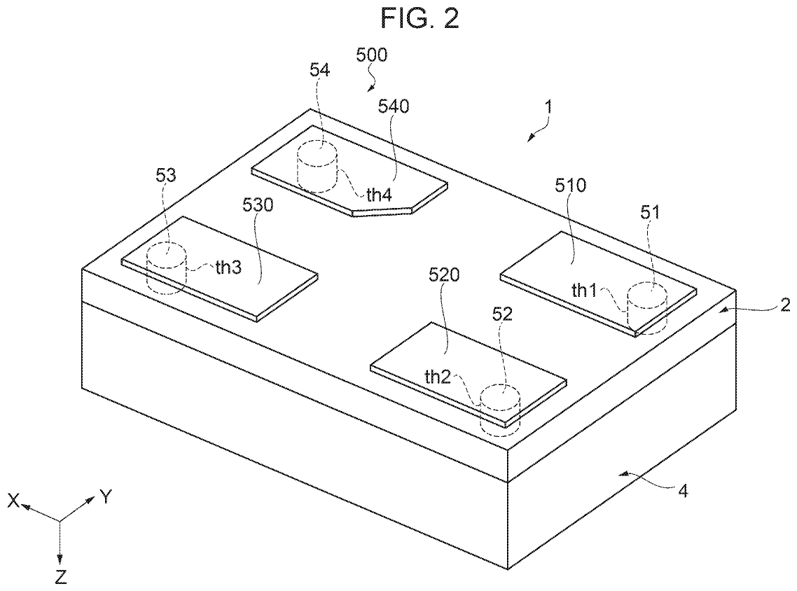

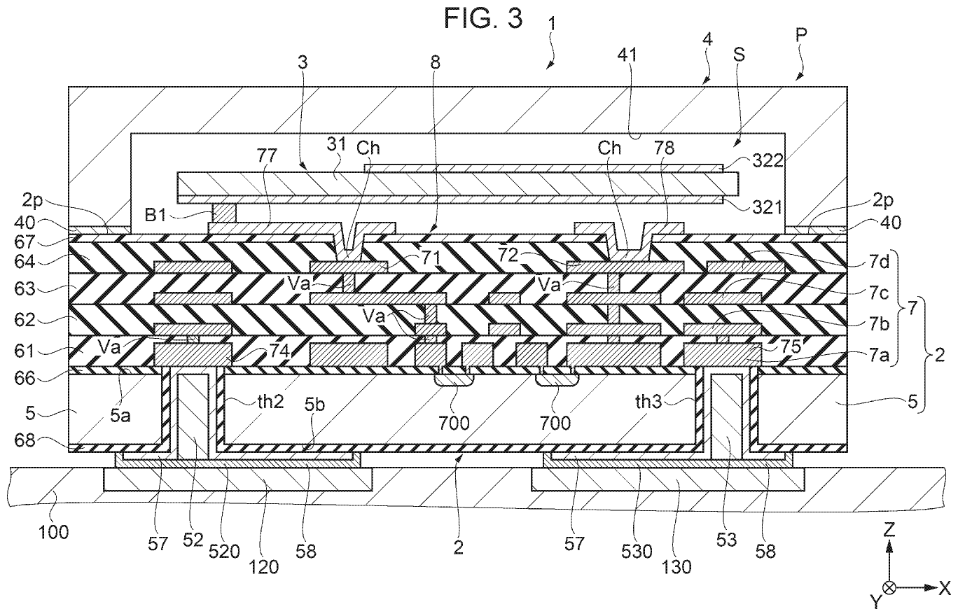

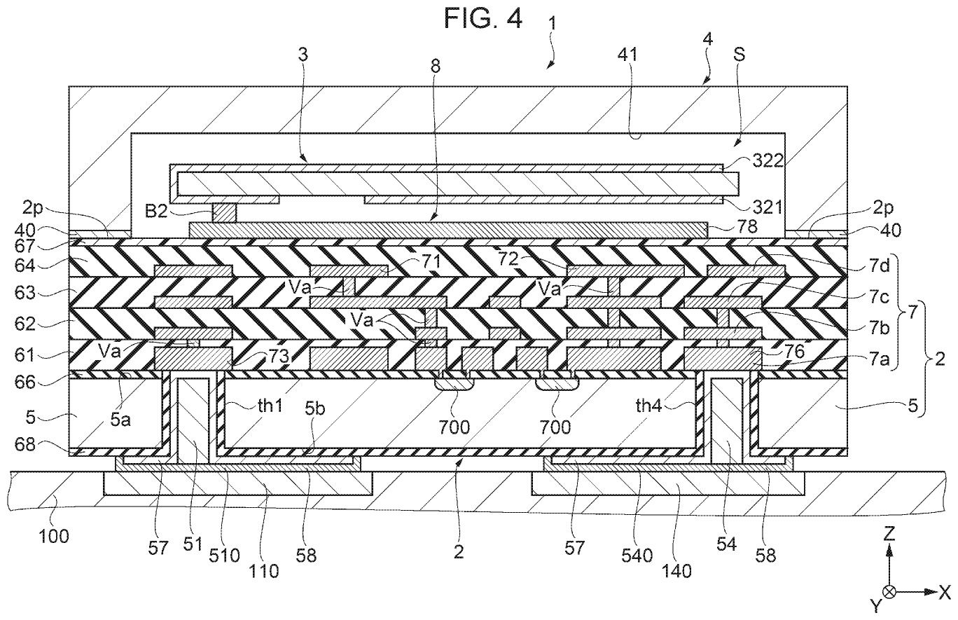

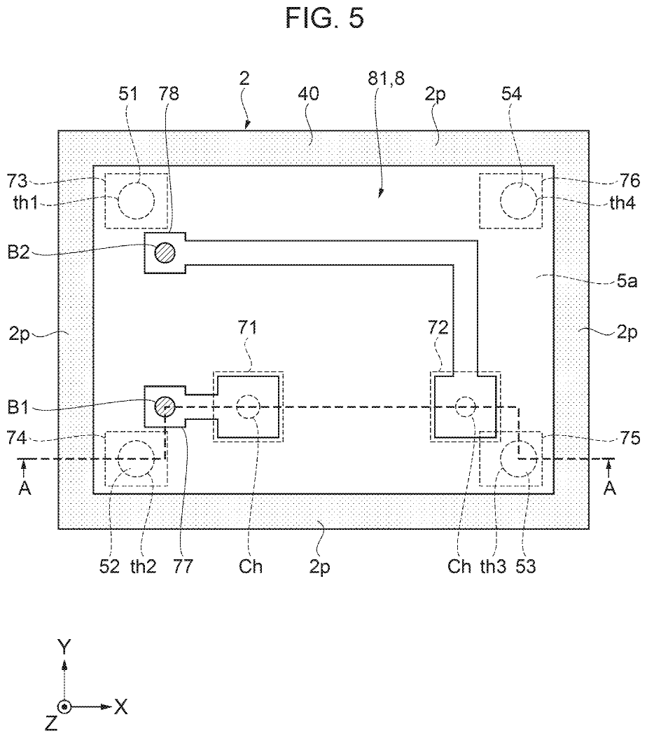

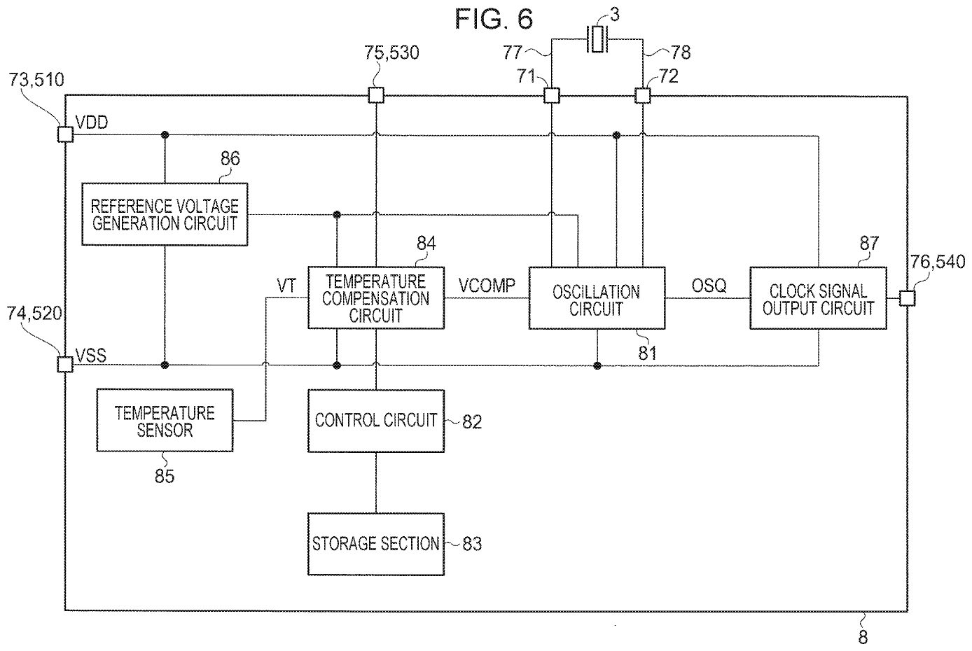

FIG. 1 is a top perspective view of the vibrator device 1 according to the present embodiment as viewed from above. FIG. 2 is a bottom perspective view of the vibrator device 1 as viewed from below. FIG. 3 is a sectional view of the vibrator device 1 taken along line A-A in FIG. 1. FIG. 4 is a sectional view of the vibrator device 1 taken along line B-B in FIG. 1. FIG. 5 is a plan view illustrating wiring 77, wiring 78, and a wiring layer 7 of a base substrate 2 of the vibrator device 1. FIG. 6 is a block diagram illustrating a circuit configuration of the vibrator device 1.

The vibrator device 1 according to the present embodiment is a wafer level packaging (WLP) type vibrator device. In the WLP type vibrator device 1, since an IC itself is packaged, it is possible to maximize the area of an integrated circuit 8 which is an IC, and realize a small and highly functional oscillator or the like. As compared with a ceramic package type vibrator device, in the ceramic package type vibrator device, the area of an IC in plan view is, for example, 50% to 60% or less of the area of a ceramic package. On the other hand, according to the WLP type vibrator device 1, it is possible to make the area of the integrated circuit 8 in plan view larger than 50% to 60% of the area of the base substrate 2. This makes it possible to provide circuit blocks for making the vibrator device 1 more highly functional in the integrated circuit 8.

As illustrated in FIG. 1, the vibrator device 1 includes the base substrate 2, a vibrator element 3, and a lid 4. In the present embodiment, the vibrator device 1 is an oscillator. More specifically, it is a quartz crystal oscillator in which the vibrator element 3 including a quartz crystal and the integrated circuit 8 including an oscillation circuit 81 are integrated into one package. The vibrator device 1 is mounted on, for example, a substrate 100 of an electronic apparatus such as a mobile phone, and outputs a reference signal to the substrate 100. The vibrator device 1 may be a micro-electromechanical systems (MEMS) oscillator. Further, the vibrator device 1 may be an inertial sensor such as a gyro sensor or an acceleration sensor, a force sensor such as an inclination sensor, or the like.

### 1.2. Configuration of Base Substrate 2

As illustrated in FIGS. 3 and 4, the base substrate 2 includes a semiconductor substrate 5 having an upper surface 5a and a lower surface 5b opposite to each other, a wiring layer 7 provided on the upper surface 5a of the semiconductor substrate 5, and a group of terminals 500 provided on the lower surface 5b of the semiconductor substrate 5. In the present embodiment, the upper surface 5a of the semiconductor substrate 5 is an example of a first surface, and the lower surface 5b of the semiconductor substrate 5 is an example of a second surface.

### 1.2.1. Semiconductor Substrate 5

The semiconductor substrate 5 is a silicon substrate. The semiconductor substrate 5 may be, for example, a substrate made of a semiconductor material other than silicon, such as Ge, GaP, GaAs, or InP.

A plurality of transistors 700 are provided on the wiring layer 7 side of the semiconductor substrate 5. The plurality of transistors 700 and the wiring layer 7 together form the integrated circuit 8 including a plurality of circuit blocks.

The semiconductor substrate 5 includes through electrodes 51, 52, 53, and 54 provided in through holes (through silicon vias) th1, th2, th3, and th4, respectively, the through holes th1, th2, th3, and th4 extending through the upper surface 5a and the lower surface 5b. As illustrated in FIG. 2, the through electrode 51 is provided at a position corresponding to a terminal 510, and is electrically connected to the terminal 510. The through electrode 52 is provided at a position corresponding to a terminal 520, and is electrically connected to the terminal 520. The through electrode 53 is provided at a position corresponding to a terminal 530, and is electrically connected to the terminal 530. The through electrode 54 is provided at a position corresponding to a terminal 540, and is electrically connected to the terminal 540. In the present embodiment, the through electrode 51 is an example of a first through electrode, the through electrode 52 is an example of a second through electrode, the through electrode 53 is an example of a third through electrode, and the through electrode 54 is an example of a fourth through electrode. Further, the terminal 510 is an example of a first terminal, the terminal 520 is an example of a second terminal, the terminal 530 is an example of a third terminal, and the terminal 540 is an example of a fourth terminal.

A passivation film 66 is provided on the upper surface 5a of the semiconductor substrate 5. A passivation film 68 is provided on the lower surface 5b of the semiconductor substrate 5. The passivation film 68 is also provided on an inner peripheral surface of each of the through holes th1, th2, th3, and th4. The passivation films 66 and 68 are, for example, silicon oxide (SiO₂). The passivation film 68 may be a resin such as polyimide. In a case where the resin is used for the passivation film 68, it is preferable to use polyimide having heat resistance which can withstand soldering when the vibrator device 1 is mounted.

The through electrodes 51, 52, 53, and 54 are copper (Cu)-plated electrodes formed by electroplating. In the present embodiment, the through electrodes 51, 52, 53, and 54 are formed by via filling plating, but may be formed by conformal plating.

A seed layer 57 is provided between each of the through electrodes 51, 52, 53, and 54 and the passivation film 68. The seed layer 57 has a two-layer stacked structure that includes a titanium (Ti) sputtered film and a copper sputtered film.

The group of terminals 500 is a group of external connection terminals of the vibrator device 1, and includes four terminals 510, 520, 530, and 540 in the present embodiment. The terminal 510 is a terminal to which a high-potential-side power supply potential (VDD) is supplied. The terminal 520 is a terminal to which a low-potential-side power supply potential (VSS) is supplied. The terminal 530 is a terminal for inputting an output enable signal OE. The terminal 540 is a terminal for outputting a clock signal CK. The number of external connection terminals is not limited to four. In the present embodiment, the VDD is an example of a first potential, and the VSS is an example of a second potential.

Each of the terminals 510, 520, 530, and 540 includes the seed layer 57 and a conductive film 58 provided so as to cover the seed layer 57. The conductive film 58 also serves as a protective film for reducing outgassing from the through electrodes 51, 52, 53, and 54. Since the through electrodes 51, 52, 53, and 54 made of copper-plated electrodes contain moisture and hydrogen, there is a possibility that the moisture and the hydrogen will be released as outgassing, and the outgassing causes a defect such as a contact failure on an electrical connection surface between each of the terminals 510, 520, 530, and 540, and each of mounted terminals 110, 120, 130, and 140 of the substrate 100.

### 1.2.2. Wiring Layer 7

The wiring layer 7 includes insulating films 61, 62, 63, and 64 and four conductive layers 7a, 7b, 7c, and 7d individually provided between the insulating films 61, 62, 63, and 64. The conductive layers 7a, 7b, 7c, and 7d are electrically connected to each other by vias Va extending through the insulating films 61, 62, and 63 provided between the layers. The conductive layers 7a, 7b, 7c, and 7d are, for example, metallic layers made of aluminum.

The conductive layers 7a, 7b, 7c, and 7d are stacked in this order from the upper surface 5a of the semiconductor substrate 5. That is, in the wiring layer 7, the conductive layer 7a is the lowermost conductive layer and is disposed closest to the semiconductor substrate 5. In addition, the conductive layer 7d is the uppermost conductive layer and is disposed closest to the vibrator element 3.

The wiring layer 7 is used for signal transmission and power supply in the integrated circuit 8, and preferably has at least four conductive layers in order to realize miniaturization by three-dimensional crossing. In the wiring layer 7, the number of conductive layers is preferably four or five, but the number of conductive layers may be six or more when the number of circuit blocks of the integrated circuit 8 increases in order to further increase the number of functions of the integrated circuit 8, enhance the functions of the integrated circuit 8, or the like.

In the wiring layer 7, a conductive layer on the upper layer side is used for signal transmission and power supply over long distances, and a conductive layer on the lower layer side is used for signal transmission and power supply over short distances. For example, a conductive layer on the transistors 700 side is used as local wiring, and connects sources, drains, and gates of the transistors 700. A conductive layer thereon connects the local wiring and global wiring as intermediate wiring, and is used for signal transmission and power supply over medium distances. The intermediate wiring may include a conductive layer that mainly includes wiring extending in the X-axis direction and a conductive layer that mainly includes wiring extending in the Y-axis direction. A conductive layer thereon serves as the global wiring for signal transmission over long distances. For example, the intermediate wiring may be wiring in each circuit block of the integrated circuit 8, and the global wiring may be wiring between the circuit blocks. Low-potential-side power supply wiring may be formed in two adjacent layers of the four conductive layers, and high-potential-side power supply wiring may be formed in the other two different layers. When power supply wiring is formed using a plurality of conductive layers, power supply can be stabilized. An inductor may be formed in the uppermost conductive layer.

The conductive layer 7d includes a conductive section 71 and a conductive section 72. The conductive section 71 is electrically connected to an excitation electrode 321 of the vibrator element 3 via a contact hole Ch and the wiring 77. The conductive section 72 is electrically connected to an excitation electrode 322 of the vibrator element 3 via a contact hole Ch and the wiring 78. In the present embodiment, the conductive section 71 is an example of a first conductive section, and the conductive section 72 is an example of a second conductive section.

The conductive layer 7a includes conductive sections 73, 74, 75, and 76. The conductive section 73 is electrically connected to the terminal 510 via the through electrode 51. The conductive section 74 is electrically connected to the terminal 520 via the through electrode 52. The conductive section 75 is electrically connected to the terminal 530 via the through electrode 53. The conductive section 76 is electrically connected to the terminal 540 via the through electrode 54. In the present embodiment, the conductive section 73 is an example of a third conductive section, the conductive section 74 is an example of a fourth conductive section, the conductive section 75 is an example of a fifth conductive section, and the conductive section 76 is an example of a sixth conductive section.

In the present embodiment, the thickness of the lowermost conductive layer 7a is made thicker than the thickness of each of the other conductive layers 7b, 7c, and 7d. The conductive layer 7a includes the conductive sections 73, 74, 75, and 76, and the through holes th1, th2, th3, and th4 are provided at positions overlapping the conductive sections 73, 74, 75, and 76, respectively, in plan view. That is, by increasing the thickness of the conductive layer 7a, it is possible to reduce the possibility that the through holes th1, th2, th3, and th4 will extend through the conductive sections 73, 74, 75, and 76 when etching is performed to form the through holes th1, th2, th3, and th4 and expose the conductive sections 73, 74, 75, and 76. Therefore, the through holes th1, th2, th3, and th4 can be easily formed, and the productivity can be improved.

### 1.2.3. Integrated Circuit 8

The base substrate 2 includes the integrated circuit 8. The integrated circuit 8 is provided on the upper surface 5a side of the semiconductor substrate 5. In other words, the integrated circuit 8 is provided between the semiconductor substrate 5 and the vibrator element 3. Such a configuration in which the integrated circuit 8 is provided on the upper surface 5a side of the semiconductor substrate 5 is referred to as a face-up type, while a configuration in which the integrated circuit 8 is provided on the lower surface 5b side of the semiconductor substrate 5 is referred to as a face-down type.

As illustrated in FIG. 6, the integrated circuit 8 includes the oscillation circuit 81, a control circuit 82, a storage section 83, a temperature compensation circuit 84, a temperature sensor 85, a reference voltage generation circuit 86, and a clock signal output circuit 87.

The oscillation circuit 81 is a circuit that generates an oscillation signal using the vibrator element 3. The oscillation circuit 81 is electrically connected to the vibrator element 3 via the conductive section 71, the wiring 77, the wiring 78, and the conductive section 72. The oscillation circuit 81 generates the oscillation signal by oscillating the vibrator element 3. For example, in a temperature-compensated crystal oscillator (TCXO) or an oven-controlled crystal oscillator (OCXO), a control voltage VCOMP corresponding to a detected temperature is input to the oscillation circuit 81, and the oscillation circuit 81 causes the vibrator element 3 to oscillate at an oscillation frequency corresponding to the control voltage VCOMP. The control voltage VCOMP is a temperature compensation voltage that compensates for the temperature characteristics of the oscillation frequency.

The clock signal output circuit 87 outputs a clock signal to the terminal 540 via the conductive section 76 based on an oscillation signal OSQ of the oscillation circuit 81. The clock signal output circuit 87 buffers the oscillation signal OSQ or a signal obtained by dividing the oscillation signal OSQ, and outputs the buffered signal as a clock signal. In the present embodiment, the clock signal is an example of an output signal.

The control circuit 82 controls each section of the integrated circuit 8. The control circuit 82 also performs interface processing with an external CPU and the like. The control circuit 82 is realized by, for example, a logic circuit such as a gate array.

The storage section 83 stores various kinds of information necessary for the operation of the integrated circuit 8. For example, the storage section 83 stores the coefficients of a polynomial for temperature compensation necessary for the temperature compensation circuit 84 to perform temperature compensation processing, and the like. The storage section 83 is, for example, a nonvolatile memory.

The temperature compensation circuit 84 outputs the control voltage VCOMP based on a temperature detection signal VT from the temperature sensor 85 and a control signal for the oscillation frequency input from the outside via the terminal 530 and the conductive section 75.

The temperature sensor 85 is a sensor that detects the temperature of the vibrator device 1. For example, the temperature sensor 85 can include a diode and the like. The temperature sensor 85 that includes a diode performs temperature detection using the temperature dependence of the forward voltage of the diode, and outputs the temperature detection signal VT.

The reference voltage generation circuit 86 is a circuit that generates a power supply voltage, a reference voltage, a bias voltage, a bias current, and the like to be supplied to each section of the integrated circuit 8. To the reference voltage generation circuit 86, the VDD is input via the terminal 510 and the conductive section 73, and the VSS is input via the terminal 520 and the conductive section 74. The reference voltage generation circuit 86 supplies the reference voltage to the temperature compensation circuit 84, and supplies the power supply voltage to the oscillation circuit 81.

### 1.3. Configuration of Vibrator Element 3

As illustrated in FIGS. 3 and 4, the vibrator element 3 includes a vibrator substrate 31 and the excitation electrodes 321 and 322.

The vibrator substrate 31 has a thickness-shear vibration mode, and is formed of an AT-cut quartz crystal substrate in the present embodiment. Since the AT-cut quartz crystal substrate has cubic frequency-temperature characteristics, the vibrator element 3 having excellent temperature characteristics is obtained.

The excitation electrode 321 is disposed on a lower surface of the vibrator substrate 31, and is electrically connected to the conductive section 71 via a bonding member B1 having conductivity, the wiring 77, and the contact hole Ch. The excitation electrode 322 is disposed on an upper surface of the vibrator substrate 31, and a portion thereof is drawn to the lower surface of the vibrator substrate 31 and is electrically connected to the conductive section 72 via a bonding member B2 having conductivity, the wiring 78, and the contact hole Ch.

The configuration of the vibrator element 3 is not limited to the above-described configuration. For example, the vibrator element 3 may be a mesa type in which a vibration region interposed between the excitation electrodes 321 and 322 protrudes from the periphery thereof, or conversely, may be an inverted mesa type in which the vibration region is recessed from the periphery thereof. In addition, bevel processing for grinding the periphery of the vibrator substrate 31 or convex processing for forming the upper surface and the lower surface as convex curved surfaces may be performed. In addition, the vibrator element 3 is not limited to a vibrator element vibrating in the thickness-shear vibration mode, and may be, for example, a vibrator element in which a plurality of vibration arms perform flexural vibration in an in-plane direction. That is, the vibrator substrate 31 is not limited to being formed of the AT-cut quartz crystal substrate, and may be formed of a quartz crystal substrate other than the AT-cut quartz crystal substrate, for example, an X-cut quartz crystal substrate, a Y-cut quartz crystal substrate, a Z-cut quartz crystal substrate, a BT-cut quartz crystal substrate, an SC-cut quartz crystal substrate, an ST-cut quartz crystal substrate, or the like. In addition, in the present embodiment, the vibrator substrate 31 includes a quartz crystal, but the present disclosure is not limited thereto. For example, the vibrator substrate 31 may be formed of a piezoelectric single crystal such as lithium niobate, lithium tantalate, lithium tetraborate, langasite crystal, potassium niobate, or gallium phosphate, or may be formed of a piezoelectric single crystal other than these. Furthermore, the vibrator element 3 is not limited to a piezoelectric driving-type vibrator element, and may be an electrostatic driving-type vibrator element using an electrostatic force.

The vibrator element 3 is bonded to the wiring 77 and the wiring 78 by the bonding members B1 and B2, respectively. Thus, the vibrator element 3 and the oscillation circuit 81 are electrically connected to each other. In the present embodiment, the bonding members B1 and B2 are bumps formed by electroless plating.

As illustrated in FIG. 5, the wiring 77 is provided so as to correspond to the conductive section 71 and the bonding member B1 in plan view, and electrically connects the conductive section 71 and the bonding member B1 to each other. The wiring 78 is provided so as to correspond to the conductive section 72 and the bonding member B2 in plan view, and electrically connects the conductive section 72 and the bonding member B2 to each other.

### 1.4. Configuration of Lid 4

The lid 4 is a silicon substrate similarly to the semiconductor substrate 5. As a result, the coefficients of linear expansion of the semiconductor substrate 5 and the lid 4 become equal to each other, generation of thermal stress due to thermal expansion is reduced, and the vibrator device 1 having excellent vibration characteristics is obtained. Further, since the vibrator device 1 can be formed by the semiconductor process, the vibrator device 1 can be efficiently manufactured with high accuracy, and the miniaturization of the vibrator device 1 can be achieved. However, the lid 4 is not particularly limited, and for example, a substrate made of a semiconductor material other than silicon, such as Ge, GaP, GaAs, or InP, may be used.

As illustrated in FIGS. 3 and 4, the lid 4 has a recessed section 41 and is bonded to an outer peripheral section 2p of an upper surface of the base substrate 2 to form a package P. The outer peripheral section 2p of the upper surface of the base substrate 2 is also an outer peripheral section of the semiconductor substrate 5 and an outer peripheral section of the wiring layer 7. The vibrator element 3 is accommodated in an accommodation space S in the package P. The accommodation space S is airtight, and is in a decompressed state, preferably in a state closer to a vacuum. Therefore, a viscous resistance is reduced, and the oscillation characteristics of the vibrator element 3 are improved. However, an atmosphere of the accommodation space S is not particularly limited.

When the through electrodes 51, 52, 53, and 54 are provided in the semiconductor substrate 5, the strength of the semiconductor substrate 5 may be reduced. In the present embodiment, in order to reduce a decrease in the strength of the semiconductor substrate 5, as illustrated in FIG. 5, the positions at which the through electrodes 51, 52, 53, and 54 are provided are made closer to the outer peripheral section 2p in plan view. Since the lid 4 is bonded to the outer peripheral section 2p, the semiconductor substrate 5 can be reinforced by the lid 4.

### 1.5. Manufacturing Method of Vibrator Device 1

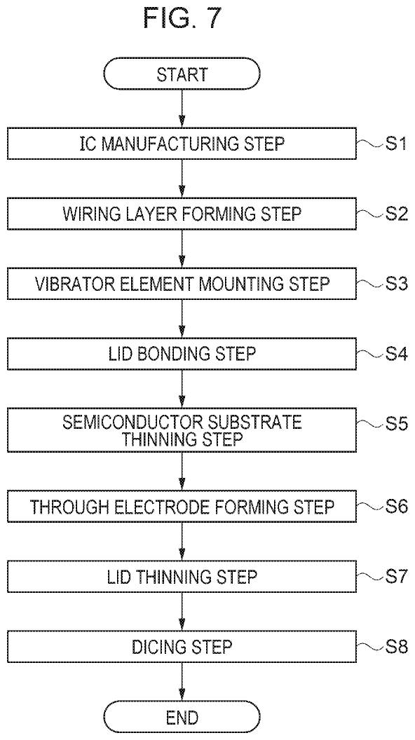

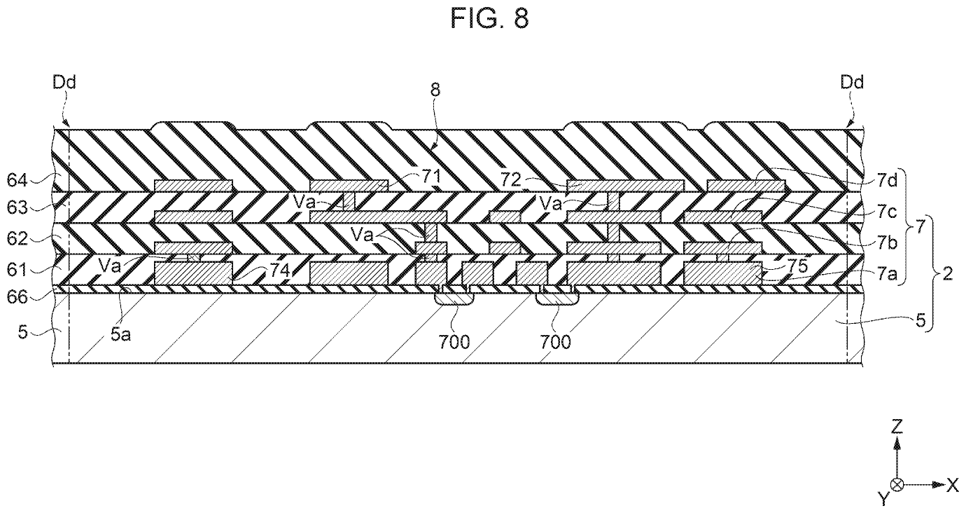

Next, a manufacturing method of the vibrator device 1 according to the present embodiment will be described with reference to FIGS. 7 to 10. FIG. 7 is a flowchart illustrating a process for manufacturing the vibrator device 1 according to the present embodiment. FIGS. 8 to 10 are sectional views illustrating an aspect of a manufacturing process, and each sectional view illustrates a cross section at a position corresponding to line A-A in FIG. 1 or FIG. 5.

As illustrated in FIG. 7, the manufacturing method of the vibrator device 1 includes an IC manufacturing step S1, a wiring layer forming step S2, a vibrator element mounting step S3, a lid bonding step S4, a semiconductor substrate thinning step S5, a through electrode forming step S6, a lid thinning step S7, and a dicing step S8. In the manufacturing method of the vibrator device 1, the vibrator device 1 is formed by using a semiconductor wafer.

In the IC manufacturing step S1, as illustrated in FIG. 8, the transistors 700 and the passivation film 66 are formed on the upper surface 5a side of the semiconductor substrate 5.

In the wiring layer forming step S2, the wiring layer 7 that includes the conductive layers 7a, 7b, 7c, and 7d, the insulating films 61, 62, 63, and 64, and the vias Va is formed on an upper surface of the passivation film 66, thereby forming the integrated circuit 8 that includes the plurality of transistors 700 and the wiring layer 7 on the upper surface 5a side of the semiconductor substrate 5.

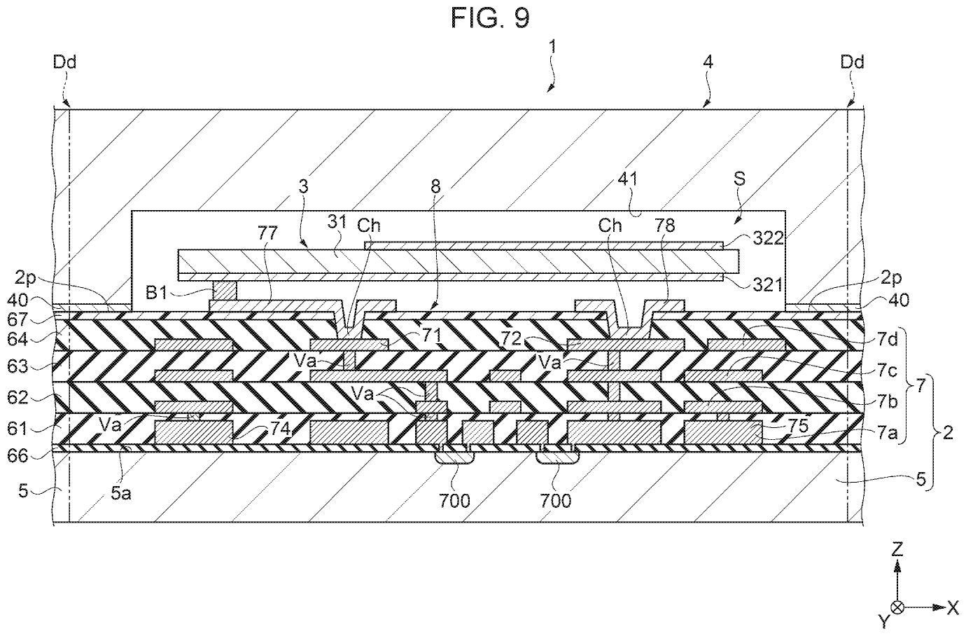

In the vibrator element mounting step S3, as illustrated in FIG. 9, the vibrator element 3 is mounted on the upper surface of the base substrate 2. In this step, first, the passivation film 67 is formed on the insulating film 64, and then a new insulating film is formed and planarized by chemical mechanical polishing (CMP). Next, the contact holes Ch that extend through the insulating film 64 and the passivation film 67 and each expose a corresponding one of the conductive section 71 and the conductive section 72 are formed, and the wiring 77 that is electrically connected to the conductive section 71 and the wiring 78 that is electrically connected to the conductive section 72 are formed. Next, the bonding members B1 and B2 are formed on the wiring 77 and the wiring 78, respectively, and the vibrator element 3 is mounted.

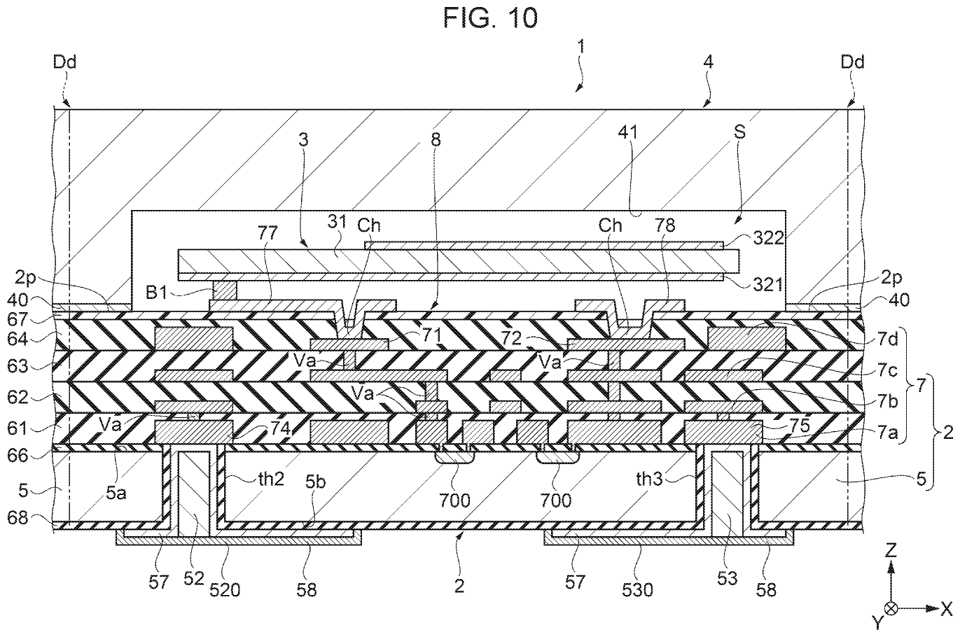

In the lid bonding step S4, as illustrated in FIG. 10, the lid 4 is bonded to the outer peripheral section 2p of the upper surface 5a of the semiconductor substrate 5 via a bonding material 40 in a decompressed state, and the vibrator element 3 is vacuum-sealed in the accommodation space S.

In the semiconductor substrate thinning step S5, the semiconductor substrate 5 is ground and polished from the lower surface 5b, and the thickness of the semiconductor substrate 5 is thinned to about 70 μm. As described above, in the vibrator device 1 according to the present embodiment, the lid 4 is bonded to the semiconductor substrate 5 before the semiconductor substrate 5 is thinned. When the semiconductor substrate 5, which is a wafer, is thinned, the lid 4 functions as a support substrate for maintaining the mechanical strength of the wafer. Therefore, in the face-up type semiconductor substrate 5, when the semiconductor substrate 5 is thinned, a wafer support system (WSS) process required in a face-down type vibrator device is not required. Therefore, the face-up type vibrator device 1 is easier to manufacture than the face-down type vibrator device.

In the through electrode forming step S6, the through electrodes 51, 52, 53, and 54 are formed between the lower surface 5b and the upper surface 5a of the semiconductor substrate 5, the through electrodes 51, 52, 53, and 54 extending through the lower surface 5b and the upper surface 5a. First, each of the through holes th1, th2, th3, and th4 extending through the semiconductor substrate 5 is formed at a position corresponding to one of the conductive sections 73, 74, 75, and 76 of the conductive layer 7a. The conductive layer 7a provided with the conductive sections 73, 74, 75, and 76 is thicker than the other conductive layers 7b, 7c, and 7d. Therefore, it is possible to reduce the possibility that the through holes th1, th2, th3, and th4 will extend through the conductive sections 73, 74, 75, and 76 when etching is performed to form the through holes th1, th2, th3, and th4.

Next, the passivation film 68 is formed on the lower surface 5b of the semiconductor substrate 5 and inner surfaces of the through holes th1, th2, th3, and th4. Next, the passivation film 68 at the bottom of the through holes th1, th2, th3, and th4 is removed, and the conductive sections 73, 74, 75, and 76 are exposed at the bottom of the through holes th1, th2, th3, and th4. Next, the seed layer 57 is formed so as to cover the lower surface 5b of the semiconductor substrate 5 and the passivation film 68 on the inner surfaces of the through holes th1, th2, th3, and th4. Next, the through electrodes 51, 52, 53, and 54 are formed on the through holes th1, th2, th3, and th4, respectively.

In the lid thinning step S7, the lid 4 is ground and polished from the upper surface, and the plate thickness of the lid 4 is thinned to about 150 μm.

In the dicing step S8, the semiconductor wafer is cut at the positions of the division lines Dd by a dicing saw or the like to be diced into individual vibrator devices 1. The length of the long side of the vibrator device 1 in plan view is, for example, about 1.2 mm to about 1.0 mm, and the length of the short side is, for example, about 1.0 mm to about 0.8 mm.

As described above, the vibrator device 1 according to the present embodiment includes: the semiconductor substrate 5 having the upper surface 5a as a first surface and the lower surface 5b as a second surface that are opposite each other, and including the through electrode 51 as a first through electrode, the through electrode 52 as a second through electrode, the through electrode 53 as a third through electrode, and the through electrode 54 as a fourth through electrode that extend through the upper surface 5a and the lower surface 5b; the wiring layer 7 provided on the upper surface 5a of the semiconductor substrate 5 and including at least four conductive layers 7a, 7b, 7c, and 7d stacked via the insulating films 61, 62, and 63, the at least four conductive layers 7a, 7b, 7c, and 7d including the conductive section 71 as a first conductive section, the conductive section 72 as a second conductive section, the conductive section 73 as a third conductive section electrically connected to the through electrode 51, the conductive section 74 as a fourth conductive section electrically connected to the through electrode 52, the conductive section 75 as a fifth conductive section electrically connected to the through electrode 53, and the conductive section 76 as a sixth conductive section electrically connected to the through electrode 54; the group of terminals 500 provided on the lower surface 5b of the semiconductor substrate 5, the group of terminals 500 including the terminal 510 as a first terminal to which the VDD as a first potential is supplied and that is electrically connected to the through electrode 51, the terminal 520 as a second terminal to which the VSS as a second potential different from the VDD is supplied and that is electrically connected to the through electrode 52, the terminal 530 as a third terminal to which the control signal is input and that is electrically connected to the through electrode 53, and the terminal 540 as a fourth terminal from which the clock signal as the output signal is output and that is electrically connected to the through electrode 54; and the vibrator element 3 provided on the upper surface 5a side of the semiconductor substrate 5 and electrically connected to the conductive section 71 and the conductive section 72 via the bonding members B1 and B2.

As described above, in the vibrator device 1 according to the present embodiment, the wiring layer 7 includes the at least four conductive layers 7a, 7b, 7c, and 7d, and the at least four conductive layers 7a, 7b, 7c, and 7d include the conductive sections 71 and 72 electrically connected to the vibrator element 3 and the conductive sections 73, 74, 75, and 76 electrically connected to the group of terminals 500. Therefore, it is possible to provide a configuration capable of realizing miniaturization. Further, for example, the area of the integrated circuit 8 of the vibrator device 1 can be maximized.

In the vibrator device 1 according to the present embodiment, the transistors 700 are provided on the wiring layer 7 side of the semiconductor substrate 5, and the conductive section 73, the conductive section 74, the conductive section 75, and the conductive section 76 are provided in the conductive layer 7a closest to the transistors 700 among the at least four conductive layers 7a, 7b, 7c, and 7d.

As described above, in the vibrator device 1 according to the present embodiment, the conductive section 73, the conductive section 74, the conductive section 75, and the conductive section 76 are provided in the conductive layer 7a closest to the transistors 700. Therefore, it is possible to provide a configuration capable of realizing miniaturization. Further, for example, the area of the integrated circuit 8 of the vibrator device 1 can be maximized.

In the vibrator device 1 according to the present embodiment, the conductive layer 7a in which the conductive section 73, the conductive section 74, the conductive section 75, and the conductive section 76 are provided is thicker than the other conductive layers 7b, 7c, and 7d.

As described above, in the vibrator device 1 according to the present embodiment, the conductive layer 7a is thicker than the other conductive layers 7b, 7c, and 7d. Therefore, the through electrodes 51, 52, 53, and 54 can be easily formed, and the productivity can be improved.

In the vibrator device 1 according to the present embodiment, the conductive section 71 and the conductive section 72 are provided in the conductive layer 7d farthest from the transistors 700 among the at least four conductive layers 7a, 7b, 7c, and 7d.

As described above, in the vibrator device 1 according to the present embodiment, the conductive section 71 and the conductive section 72 are provided in the conductive layer 7d farthest from the transistors 700. Therefore, it is possible to provide a configuration capable of realizing miniaturization. Further, for example, the area of the integrated circuit 8 of the vibrator device 1 can be maximized.

The vibrator device 1 according to the present embodiment includes the lid 4 that is bonded to the semiconductor substrate 5 and forms the accommodation space S for accommodating the vibrator element 3 between the lid 4 and the semiconductor substrate 5.

Therefore, according to the vibrator device 1 of the present embodiment, it is possible to realize the vibrator device 1 having a configuration suitable for miniaturization. Further, for example, the area of the integrated circuit 8 of the vibrator device 1 can be maximized.

The present disclosure was described above based on a preferred embodiment, but the present disclosure is not limited to the above embodiment. In addition, it is possible to replace the configuration of each section of the present disclosure with any configuration that exerts the same function as the above embodiment, and to add any configuration.

What is claimed is:

1. A vibrator device comprising:
a semiconductor substrate having a first surface and a second surface that are opposite each other, and including a first through electrode, a second through electrode, a third through electrode, and a fourth through electrode that extend through the first surface and the second surface;
a wiring layer provided on the first surface of the semiconductor substrate and including at least four conductive layers stacked via insulating films, the at least four conductive layers including a first conductive section, a second conductive section, a third conductive section electrically connected to the first through electrode, a fourth conductive section electrically connected to the second through electrode, a fifth conductive section electrically connected to the third through electrode, and a sixth conductive section electrically connected to the fourth through electrode;
a group of terminals provided on the second surface of the semiconductor substrate, the group of terminals including a first terminal to which a first potential is supplied and that is electrically connected to the first through electrode, a second terminal to which a second potential different from the first potential is supplied and that is electrically connected to the second through electrode, a third terminal to which a control signal is input and that is electrically connected to the third through electrode, and a fourth terminal from which an output signal is output and that is electrically connected to the fourth through electrode; and
a vibrator element provided on the first surface side of the semiconductor substrate and electrically connected to the first conductive section and the second conductive section via bonding members.

2. The vibrator device according to claim 1, wherein
a transistor is provided on the wiring layer side of the semiconductor substrate, and
the third conductive section, the fourth conductive section, the fifth conductive section, and the sixth conductive section are provided in a conductive layer closest to the transistor among the at least four conductive layers.

3. The vibrator device according to claim 2, wherein the conductive layer in which the third conductive section, the fourth conductive section, the fifth conductive section, and the sixth conductive section are provided is thicker than other conductive layers.

4. The vibrator device according to claim 2, wherein the first conductive section and the second conductive section are provided in a conductive layer farthest from the transistor among the at least four conductive layers.

5. The vibrator device according to claim 1, further comprising a lid that is bonded to the semiconductor substrate and forms an accommodation space for accommodating the vibrator element between the lid and the semiconductor substrate.
